(19) United States
(12) Patent Application Publication
(10) Pub. No.: US 2008/0124828 A1
(43) Pub. Date: May 29, 2008

(54) Fabrication processes of a MEMS alloy probe

(75) Inventors: Hsiang-Ming Huang, Tainan (TW); An-Hong Liu, Tainan (TW); Shu-Ching Ho, Tainan (TW); Yi-Chang Lee, Tainan (TW); Yeong-Jyh Lin, Tainan (TW)

Correspondence Address: TROXELL LAW OFFICE PLLC, SUITE 1404, 5205 LEESBURG PIKE, FALLS CHURCH, VA, 22041, US

(73) Assignees: ChipMOS Technologies (Bermuda) Ltd.; ChipMOS Technologies Inc.

(21) Appl. No.: 11/601,753

(22) Filed: Nov. 20, 2006

(30) Foreign Application Priority Data
Jul. 14, 2006 (TW) 095125908

(51) Int. Cl. H01L 21/56

(52) U.S. Cl. 438/51; 257/E21.502

(57) ABSTRACT

MEMS processes for fabrication of a MEMS alloy probe are revealed. Multiple layers of the MEMS alloy probe are formed on the substrate in sequences as a first surface layer, a first conductive layer, a core layer, a second conductive layer, and a second surface layer where the width of the first conductive layer is smaller than the one of first surface layer so that all the exposed edges of the first surface layer are not covered by the first conductive layer. The second surface layer is extended from the sidewalls of the core layer to the exposed edges of the first surface layer to encapsulate the core layer, the first conductive layer, and the second conductive layer. The MEMS alloy probe fabricated by the MEMS processes can eliminate the issue of oxidation.

### FIELD OF THE INVENTION

The present invention relates to fabrication processes of probes, and more particularly, to the fabrication processes of MEMS alloy probes for anti-contamination and anti-oxidation.

### BACKGROUND OF THE INVENTION

Probes on a probe card are one of the key components of semiconductor testing to probe electrical terminals or testing pads of wafers, BGA packages, TCP components, COF components, etc. As the feature dimensions of IC components in wafers are getting smaller and smaller, the conventional probe manufactured by casting or electroplating and manual probe placement are gradually replaced by high accurate MEMS probes manufactured and placed by MEMS processes. However, even the dimensions and shapes of the MEMS probes can be miniaturized and varied, the existing MEMS probes still have the issue of oxidation.

As shown in FIG. 1, a conventional probe 100 fabricated by MEMS processes includes a first surface layer 111, a first conductive layer 121, a core layer 130, a second conductive layer 122 and a second surface layer 112 which are fabricated layers by layers through electroplating.

As shown in FIG. 2, the conventional probe 100 is fabricated by photolithography and electroplating of MEMS processes where a slot is formed by a photoresist layer through spin coating, exposure, and development. After multiple electroplating processes, the first surface layer 111 of the probe 100 is formed on the sacrificial layer 11 of the substrate 10, the first conductive layer 121 on the first surface layer 111, the core layer 130 on the first conductive layer 121, the second conductive layer 122 on the core layer 130, and the second surface layer 112 on the second conductive layer 122. As shown in FIG. 1 and FIG. 2, the width of the core layer 130 of the conventional probe 100 is the same as the ones of the first surface layer 111, the first conductive layer 121, the second conductive layer 122, and the second surface layer 112, therefore, the exposed sidewalls 131 of the core layer 130 are not covered by the first surface layer 111 nor by the second surface layer 112. Because of the high temperature and bias during semiconductor testing, the exposed sidewalls 131 of the core layer 130 are easily oxidized leading to shorter lifetime of probes, peeling between electroplated layers, and transmission delay of the signals. Eventually, the testing results will not be accurate.

### SUMMARY OF THE INVENTION

The main purpose of the present invention is to provide MEMS processes for fabrication of MEMS alloy probes to eliminate the issues of oxidation and contamination of MEMS probes.

The second purpose of the present invention is to provide MEMS processes for fabrication of MEMS alloy probes to eliminate the interface gaps between the core layer and the conductive layers and to release the internal stress during fabrication so that the MEMS probes are not only tough and strong but also more flexible with better electrical conductivity.

According to the present invention, MEMS processes for fabrication of alloy MEMS probes are disclosed. A substrate is provided where a first surface layer of the MEMS probe is formed on the substrate. A first conductive layer of the MEMS probe is formed on the first surface layer where the width of the first conductive layer is smaller than the one of the first surface layer so that all the edges of the first surface layer are not covered by the first conductive layer. A core layer of the MEMS probe is formed on the first conductive layer, then a second conductive layer of the MEMS probe on the core layer and the second surface layer on the second conductive layer where the second surface layer is extended to cover the edges of the first surface layer to encapsulate the core layer, the first conductive layer, and the second conductive layer.

### DESCRIPTION OF THE DRAWINGS

FIG. 1 shows a partial three-dimensional view of a conventional MEMS probe.

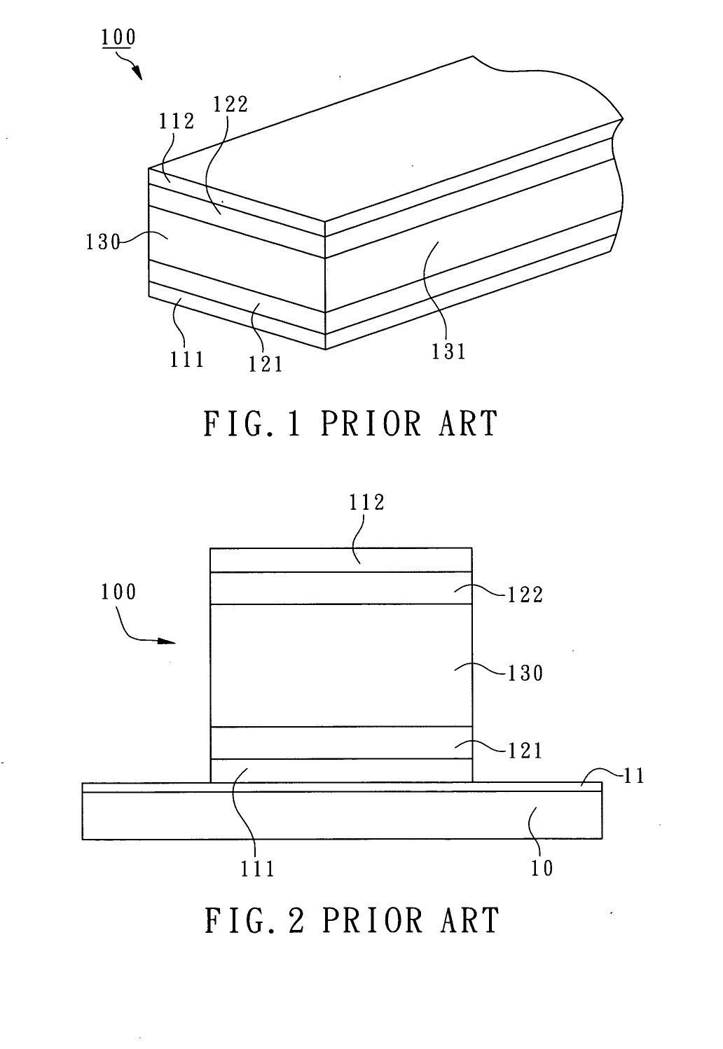

FIG. 2 shows a cross sectional view of the conventional MEMS probe on a substrate.

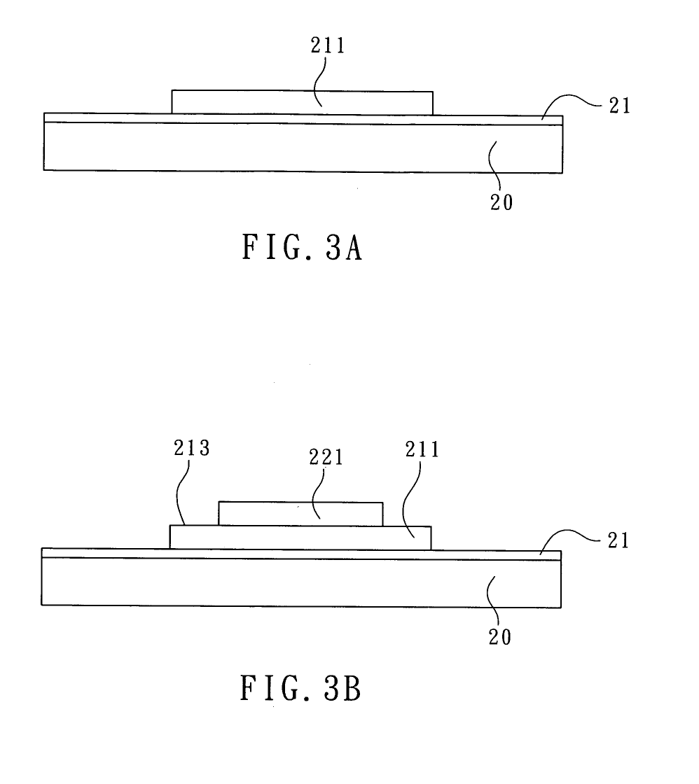

FIG. 3A to 3E show the cross sectional views of a MEMS alloy probe during MEMS fabrication processes according to the first embodiment of the present invention.

FIG. 4 shows a partial three-dimensional view of the MEMS alloy probe according to the first embodiment of the present invention.

FIG. 5A to 5B show the cross sectional views of a MEMS alloy probe during annealing of MEMS fabrication processes according to the second embodiment of the present invention.

### DETAIL DESCRIPTION OF THE INVENTION

Please refer to the attached drawings, the present invention will be described by means of embodiment(s) below.

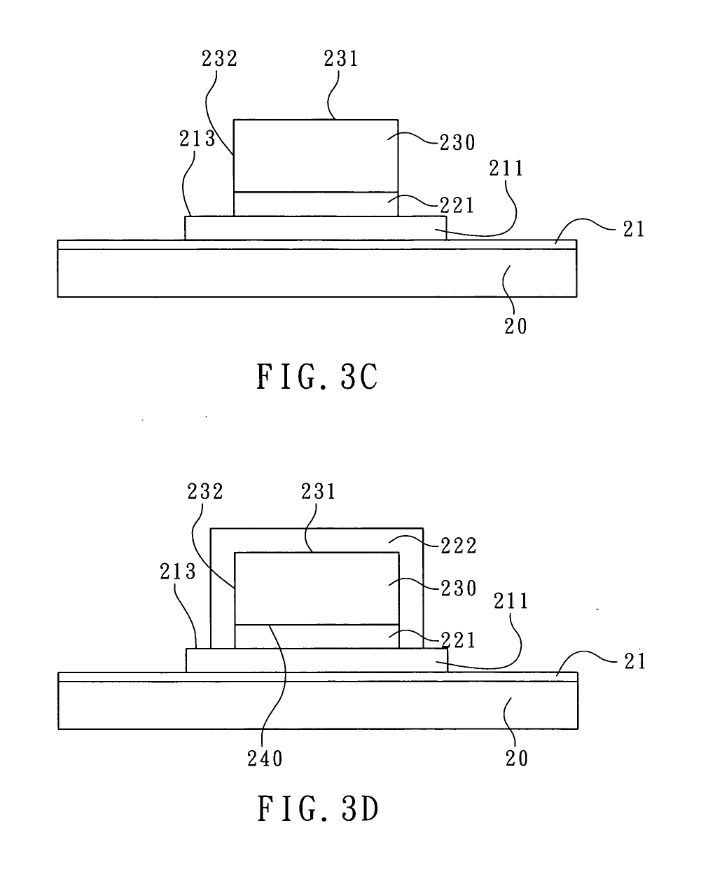

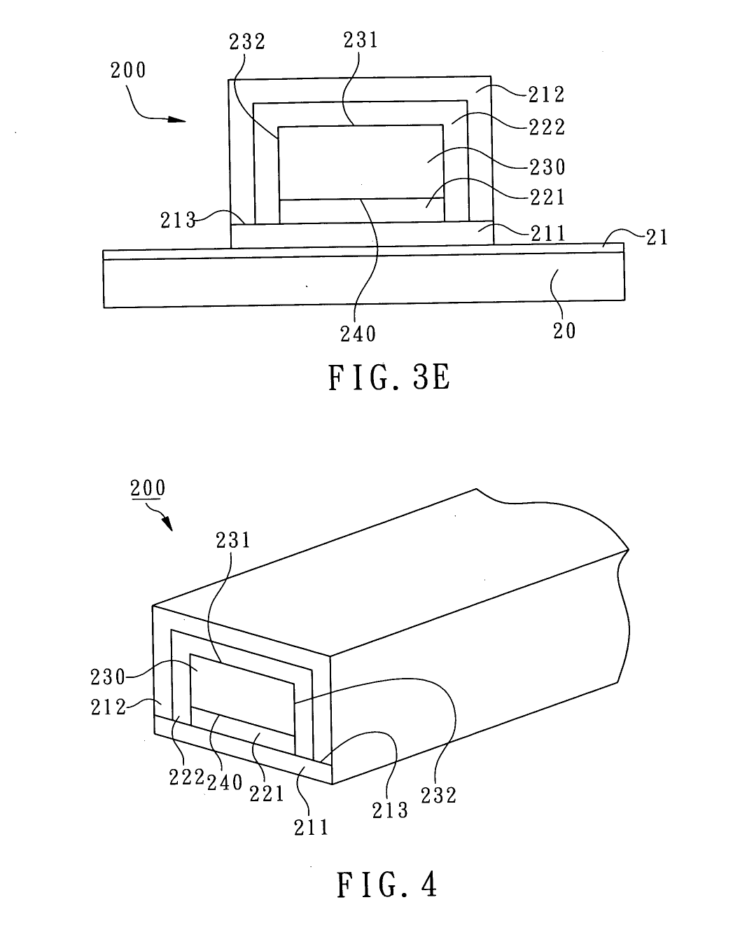

According to the first embodiment of the present invention, the MEMS fabrication processes of a MEMS alloy probe 200 are revealed from FIG. 3A to 3E, and FIG. 4 is the partial three-dimensional view of the fabricated MEMS alloy probe.

Firstly, as shown in FIG. 3A, a substrate 20 is provided where the first surface layer 211 of the MEMS alloy probe 200 is formed on the substrate 20. A sacrificial layer 21 is pre-formed on the substrate 20 where the substrate 20 can be a semiconductor wafer, a ceramic substrate, a glass substrate, or a stainless steel plate. Moreover, the sacrificial layer 21 is easily to be removed or peeled such as nano peeling material. An electroplated seed layer, not shown in the figure, can be formed on the first surface layer 211 by sputtering, then a photoresist layer is formed on the first surface layer 211 to form the patterns of the MEMS alloy probes. In the present embodiment, the first surface layer is stripe-like.

As shown in FIG. 3B, a first conductive layer 221 of the MEMS alloy probe 200 is formed on the first surface layer 211 where the shape of the first conductive layer 221 can be any kinds of stripes. The width of the first conductive layer 221 is smaller than the one of the first surface layer 211 so that all the exposed edges 213 of the first surface layer 211 are not covered by the first conductive layer 221. In this embodiment, the exposed edges 213 are connected to be a closed ring. Another photoresist layer, not shown in the figure, is used to define the electroplated area for the formation of the first conductive layer 221. Then, as shown in FIG. 3C, a core layer 230 of the MEMS alloy probe 200 is formed on the first conductive layer 221 where the core layer 230 has a top surface 231 and two sidewalls 232.

As shown in FIG. 3D, a second conductive layer 222 is formed on the top surface 231 of the core layer 230. In the present embodiment, the second conductive layer 222 is extended to the sidewalls 232 of the core layer 230 and is connected to the first conductive layer 221 to increase the transmission speed and to prevent the oxidation of the core layer 230.

Then, as shown in FIG. 3E, a second surface layer 212 is formed on the second conductive layer 222 where the second surface layer 222 is extended from the sidewalls of the MEMS alloy probe 200 to the exposed edges 213 of the first surface layer 211 to encapsulate the core layer 230, the first conductive layer 221, and the second conductive layer 222. Finally, a MEMS alloy probe 200 fabricated by MEMS processes can be peeled or etching from the substrate 20.

As shown in FIG. 4, the sidewalls 232 of the core layer 230 are covered by the second surface layer 212, so as the second conductive layer 222. Therefore, the core layer 230 of the MEMS alloy probe 200 is encapsulated by the first surface layer 211 and the second surface layer 212 without any exposed surface when installing on a probe card. The oxidation of the sidewalls of the core layer in a conventional MEMS probe is eliminated. Accordingly, the MEMS alloy probe 200 fabricated can eliminate the issues of oxidation and contamination of a conventional MEMS probe.

Furthermore, the materials of the first surface layer 211 and the second surface layer 212 contain Palladium (Pd), to prevent oxidation and contamination. The materials of the first conductive layer 221 and the second conductive layer 222 contain gold (Au), to increase electrical conductivity and to prevent oxidation. Moreover, the material of the core layer 230 contains Nickel (Ni), and other metal additives to become tough and strong with good flexibility, copper, tungsten, titanium, palladium, silver, cobalt, molybdenum, iron for example.

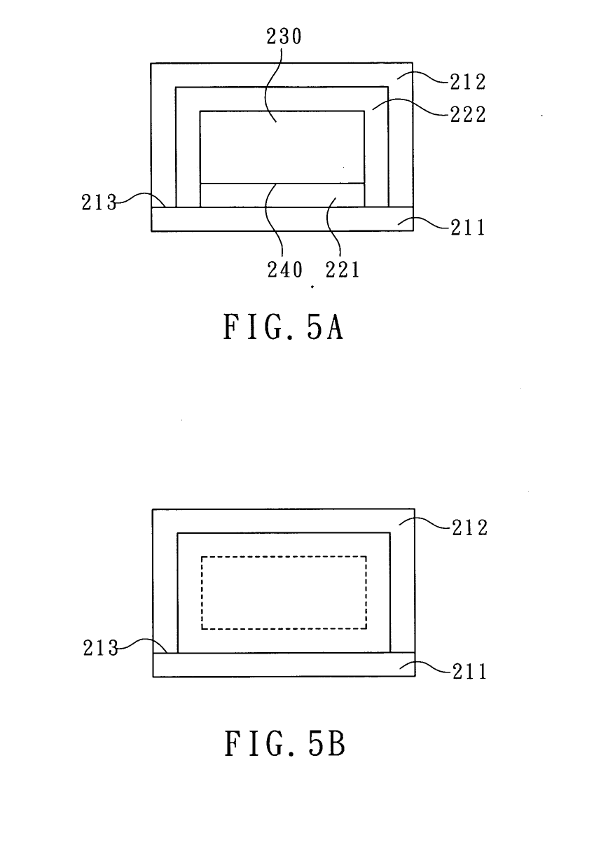

In the second embodiment of the present invention, as shown from FIG. 5A to 5B, another MEMS processes for fabrication of a MEMS alloy probe 200 are disclosed. The major MEMS processes are the same as the ones of the first embodiment but further comprise an annealing step. The annealing step is to heat up the MEMS alloy probe 200 and then slowly drop the temperature to reinforce the flexibility of the core layer 230 and to eliminate the internal stress inside the MEMS alloy probe 200. As shown in FIG. 5A, before the annealing step, an interface gap 240 may be existed between the core layer 230 and the second conductive layer 222. After annealing, the interface gap 240 between the core layer 230 and the second conductive layer 222 or between the core layer 230 and the first conductive layer 221 can be eliminated (as shown in FIG. 5B) so that the adhesion between the core layer 230 and the first conductive layer 221 and between the core layer 230 and the second conductive layer 221 can be enhanced.

The above description of embodiments of this invention is intended to be illustrative and not limiting. Other embodiments of this invention will be obvious to those skilled in the art in view of the above disclosure.

What is claimed is:

1. A fabrication process of a MEMS alloy probe, comprising:
providing a substrate;
forming a first surface layer of the MEMS alloy probe on the substrate;
forming a first conductive layer of the MEMS ally probe on the first surface layer, where the width of the first conductive layer is smaller than the one of the first surface layer to expose all the edges of the first surface layer without covering by the first conductive layer;
forming a core layer of the MEMS alloy probe on the first conductive layer;
forming a second conductive layer of the MEMS alloy probe on the core layer; and
forming a second surface layer of the MEMS alloy probe on the second conductive layer, wherein the second surface layer is extended to the exposed edges of the first surface layer to encapsulate the core layer, the first conductive layer, and the second conductive layer.

2. The fabrication process of claim 1, wherein a sacrificial layer is pre-formed on the substrate before the formation of the MEMS alloy probe.

3. The fabrication process of claim 1, wherein the second conductive layer is extended from sidewalls of the core layer to the first conductive layer.

4. The fabrication process of claim 1, further comprising an annealing step to reinforce the flexibility of the core layer and to eliminate the internal stress.

5. The fabrication process of claim 4, wherein the annealing step is performed to eliminate the interface gaps between the core layer and the first conductive layer and between the core layer and the second conductive layer.

6. The fabrication process of claim 1, wherein the materials of the first surface layer and the second surface layer contain Palladium (Pd).

7. The fabrication process of claim 1, wherein the materials of the first conductive layer and the second conductive layer contain gold (Au).

8. The fabrication process of claim 1, wherein the material of the core layer contains Nickel (Ni).
